(19) United States
(12) Patent Application Publication
(10) Pub. No.: US 2019/0379321 A1
(43) Pub. Date: Dec. 12, 2019

(54) SOLAR ROOF TILE CONNECTORS

(71) Applicant: TESLA, INC., Palo Alto, CA (US)

(72) Inventor: Peter P. Nguyen, Hayward, CA (US)

(73) Assignee: TESLA, INC., Palo Alto, CA (US)

(21) Appl. No.: 16/006,645

(22) Filed: Jun. 12, 2018

(51) Int. Cl. H02S 20/25; H01L 31/05; H01L 31/043; H01L 31/02

(52) U.S. Cl. CPC H02S 20/25; H01L 31/0201; H01L 31/043; H01L 31/0504

(57) ABSTRACT

One embodiment can provide a photovoltaic roof tile. The photovoltaic roof tile can include a plurality of photovoltaic structures positioned between a front cover and a back cover, a bridge electrode coupled to a front-side busbar belonging to a photovoltaic structure, and a metallic strip positioned on a back side of the bridge electrode. The bridge electrode can include a substrate and at least one metallization layer positioned on a back surface of the substrate, and the metallization layer is electrically coupled to both the front-side busbar and the metallic strip, thereby enabling electrical coupling between the front-side busbar and the metallic strip.

### BACKGROUND

### Field

This disclosure is generally related to photovoltaic (or “PV”) tiles. More specifically, this disclosure is related to electrodes for interconnecting solar roof tiles.

### Related Art

In residential and commercial solar energy installations, a building's roof typically is installed with photovoltaic (PV) modules, also called PV or solar panels, that can include a two-dimensional array (e.g., 6×12) of solar cells. A PV roof tile (or solar roof tile) can be a particular type of PV module offering weather protection for the home and a pleasing aesthetic appearance, while also functioning as a PV module to convert solar energy to electricity. The PV roof tile can be shaped like a conventional roof tile and can include one or more solar cells encapsulated between a front cover and a back cover, but typically encloses fewer solar cells than a conventional solar panel.

The front and back covers can be fortified glass or other material that can protect the PV cells from the weather elements. Note that a typical roof tile may have a dimension of 15 in×8 in =120 in²=774 cm², and a typical solar cell may have a dimension of 6 in×6 in =36 in²=232 cm². Similar to a conventional PV panel, the PV roof tile can include an encapsulating layer, such as an organic polymer. A lamination process can seal the solar cells between the front and back covers. Like conventional PV panels, electrical interconnections are needed within each PV roof tile and among different roof tiles.

### SUMMARY

One embodiment can provide a photovoltaic roof tile. The photovoltaic roof tile can include a plurality of photovoltaic structures positioned between a front cover and a back cover, a bridge electrode coupled to a front-side busbar belonging to a photovoltaic structure, and a metallic strip positioned on a back side of the bridge electrode. The bridge electrode can include a substrate and at least one metallization layer positioned on a back surface of the substrate, and the metallization layer is electrically coupled to both the front-side busbar and the metallic strip, thereby enabling electrical coupling between the front-side busbar and the metallic strip.

In a variation on this embodiment, a respective photovoltaic structure can include a front-side edge busbar positioned near an edge of a front surface and a back-side edge busbar positioned near an opposite edge of a back surface. The plurality of photovoltaic structures can be arranged in such a way that the back-side edge busbar of a first photovoltaic structure overlaps the front-side edge busbar of an adjacent photovoltaic structure, thereby resulting in the plurality of photovoltaic structures forming a serially coupled string.

In a further variation, the metallization layer can be coupled to a front-side edge busbar positioned at an end of the serially coupled string.

In a variation on this embodiment, the substrate of the bridge electrode comprises one of: a Si substrate, a glass substrate, and a plastic substrate.

In a variation on this embodiment, the bridge electrode can include one or more of: an Al layer configured to substantially cover the back surface of the substrate and a contact layer comprising Ag.

In a further embodiment, the contact layer can include an edge busbar and a plurality of contact pads.

In a further embodiment, the bridge electrode can be arranged in such a way that the edge busbar of the contact layer overlaps the front-side busbar of the photovoltaic structures.

In a further embodiment, the metallic strip can be coupled to the contact pads.

In a further embodiment, the Al layer and the contact layer can be formed using a screen printing technique.

In a variation on this embodiment, the photovoltaic roof tile can further include an external connector coupled to a back-side busbar belonging to a photovoltaic structure.

One embodiment can provide a method for fabricating a photovoltaic roof tile. The method can include: forming a cascaded string of photovoltaic structures, forming a bridge electrode, and attaching the bridge electrode to a front-side busbar belonging to a photovoltaic structure. The bridge electrode can include a substrate and at least one metallization layer positioned on a back surface of the substrate. The method can further include attaching a metallic strip to a back surface of the bridge electrode, wherein the metallic strip is electrically coupled to the front-side busbar via the metallization layer of the bridge electrode; and laminating the cascaded string of photovoltaic structures, the bridge electrode, and the attached metal strip between the front cover and a back cover.

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BRIEF DESCRIPTION OF THE FIGURES

FIG. 1 shows an exemplary configuration of PV roof tiles on a house.

FIG. 2 shows the perspective view of an exemplary photovoltaic roof tile, according to an embodiment.

FIG. 3 shows a cross-section of an exemplary photovoltaic roof tile, according to an embodiment.

FIG. 4A illustrates an exemplary configuration of a multi-tile module, according to one embodiment.

FIG. 4B illustrates a cross-section of an exemplary multi-tile module, according to one embodiment.

FIG. 5A illustrates a serial connection between three adjacent cascaded photovoltaic strips, according to one embodiment.

FIG. 5B illustrates the side view of the string of cascaded strips, according to one embodiment.

FIG. 5C illustrates an exemplary solar roof tile, according to one embodiment.

FIG. 6A shows the top view of an exemplary multi-tile module, according to one embodiment.

FIG. 6B shows a detailed view of an exemplary strain-relief connector, according to one embodiment.

FIG. 7A shows the front surface of an exemplary bridge electrode, according to one embodiment.

FIG. 7B shows the back surface of the exemplary bridge electrode, according to one embodiment.

FIG. 7C shows the coupling between a metal strip (e.g., a Cu strip) and the bridge electrode, according to one embodiment.

FIG. 8A shows a cross-sectional view of a cascaded photovoltaic string coupled to a bridge electrode, according to an embodiment.

FIG. 8B shows a cross-sectional view of a cascaded photovoltaic string coupled to a bridge electrode, according to an embodiment.

FIG. 9 shows the top view of an exemplary multi-tile module, according to one embodiment.

FIG. 10 presents a flowchart illustrating an exemplary process for fabricating a photovoltaic tile module, according to an embodiment.

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

### Overview

Embodiments of the invention solve at least the technical problem of enabling low-cost and reliable electrical interconnections among solar roof tiles. More specifically, a silicon-based bridge chip can be used for electrical coupling between an edge busbar of a cascaded string and a metallic tab or tabbing strip. Such a metallic tab or tabbing strip can then be used for electrical interconnections among solar roof tiles. Compared to approaches that rely on expensive and relatively fragile stamped electrodes for electrical coupling between the edge busbar and metallic tab, this bridge-chip approach reduces fabrication cost and enhances the reliability of the electrical connections.

### PV Roof Tiles and Multi-Tile Modules

A PV roof tile (or solar roof tile) is a type of PV module shaped like a roof tile and typically enclosing fewer solar cells than a conventional solar panel. Note that such PV roof tiles can function as both PV cells and roof tiles at the same time. PV roof tiles and modules are described in more detail in U.S. Provisional Patent Application No. 62/465,694, Attorney Docket No. P357-1PUS, entitled “SYSTEM AND METHOD FOR PACKAGING PHOTOVOLTAIC ROOF TILES” filed Mar. 1, 2017, which is incorporated herein by reference. In some embodiments, the system disclosed herein can be applied to PV roof tiles and/or other types of PV module.

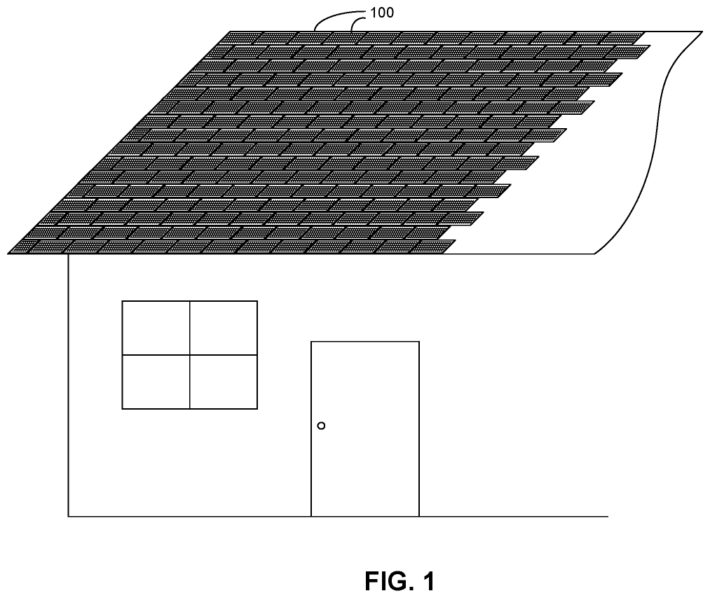

FIG. 1 shows an exemplary configuration of PV roof tiles on a house. PV roof tiles 100 can be installed on a house like conventional roof tiles or shingles. Particularly, a PV roof tile can be placed with other tiles in such a way as to prevent water from entering the building.

A PV roof tile can enclose multiple solar cells or PV structures, and a respective PV structure can include one or more electrodes, such as busbars and finger lines. The PV structures within a PV roof tile can be electrically, and optionally, mechanically coupled to each other. For example, multiple PV structures can be electrically coupled together by a metallic tab, via their respective busbars, to create serial or parallel connections. Moreover, electrical connections can be made between two adjacent tiles, so that a number of PV roof tiles can jointly provide electrical power.

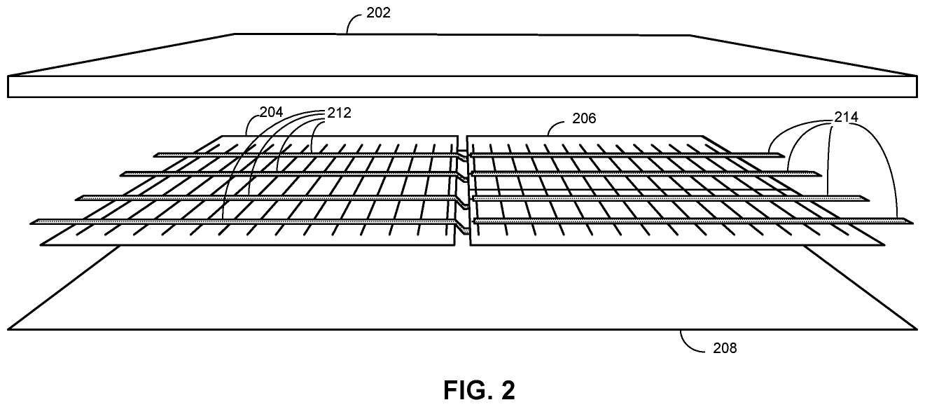

FIG. 2 shows the perspective view of an exemplary photovoltaic roof tile, according to an embodiment. Solar cells 204 and 206 can be hermetically sealed between top glass cover 202 and backsheet 208, which jointly can protect the solar cells from various weather elements. In the example shown in FIG. 2, metallic tabbing strips 212 can be in contact with the front-side electrodes of solar cell 204 and extend beyond the left edge of glass 202, thereby serving as contact electrodes of a first polarity of the PV roof tile. Tabbing strips 212 can also be in contact with the back of solar cell 206, creating a serial connection between solar cell 204 and solar cell 206. On the other hand, tabbing strips 214 can be in contact with front-side electrodes of solar cell 206 and extend beyond the right edge of glass cover 202, serving as contact electrodes of a second polarity of the PV roof tile.

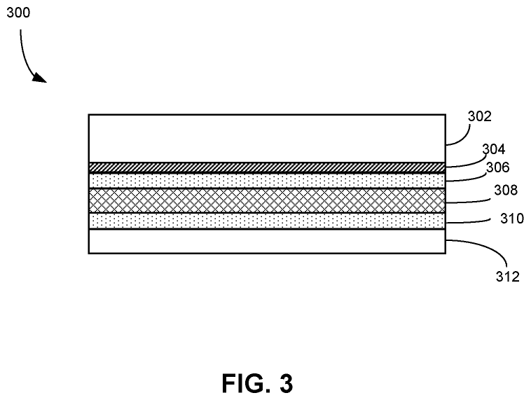

FIG. 3 shows a cross-section of an exemplary photovoltaic roof tile, according to an embodiment. Solar cell or array of solar cells 308 can be encapsulated between top glass cover 302 and back cover 312, which can be fortified glass or a regular PV backsheet. Top encapsulant layer 306, which can be based on a polymer, can be used to seal top glass cover 302 and solar cell or array of solar cells 308. Specifically, encapsulant layer 306 may include polyvinyl butyral (PVB), thermoplastic polyolefin (TPO), ethylene vinyl acetate (EVA), or N,N′-diphenyl-N,N′-bis(3-methylphenyl)-1,1′-diphenyl-4,4′-diamine (TPD). Similarly, lower encapsulant layer 310, which can be based on a similar material, can be used to seal array of solar cells 308 and back cover 312. A PV roof tile can also contain other optional layers, such as an optical filter or coating layer or a layer of nanoparticles for providing desired colors. In the example of FIG. 3, module or roof tile 300 also contains an optical filter layer 304.

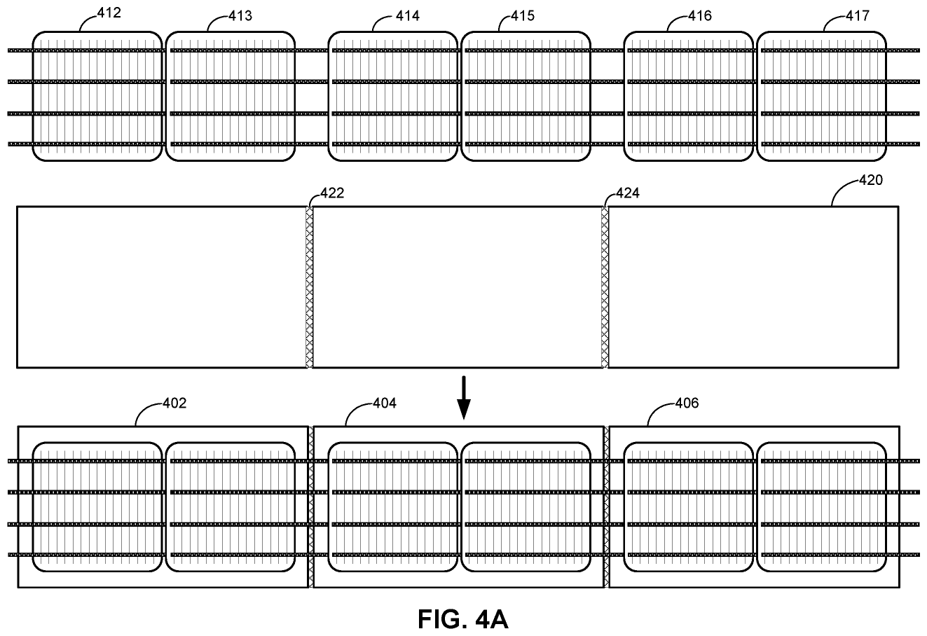

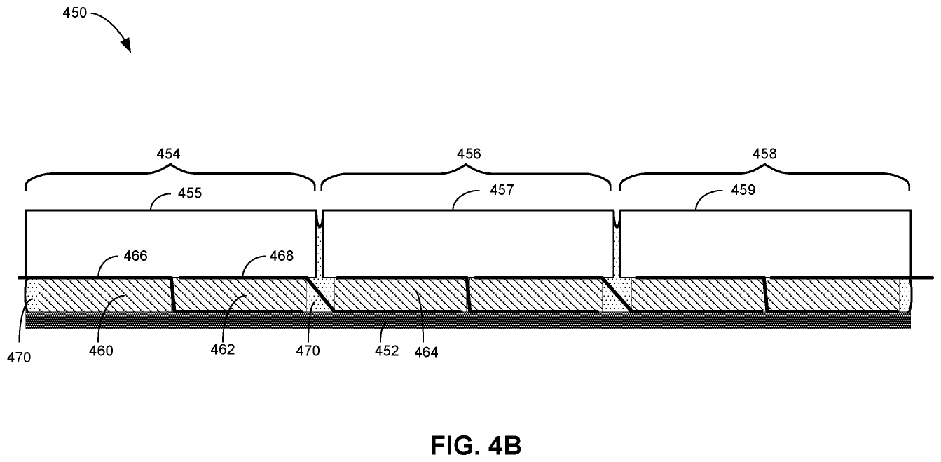

To facilitate more scalable production and easier installation, multiple photovoltaic roof tiles can be fabricated together, while the tiles are linked in a rigid or semi-rigid way. FIG. 4A illustrates an exemplary configuration of a multi-tile module, according to one embodiment. In this example, three PV roof tiles 402, 404, and 406 can be manufactured together. During fabrication, solar cells 412 and 413 (corresponding to tile 402), 414 and 415 (corresponding to tile 404), and 416 and 417 (corresponding to tile 406) can be laid out with tabbing strips interconnecting their corresponding busbars, forming a connection in series. Furthermore, these six solar cells can be laid out on a common backsheet. Subsequently, front-side glass cover 420 can be sealed onto these six PV cells.

It is possible to use a single piece of glass as glass cover 420. In one embodiment, grooves 422 and 424 can be made on glass cover 420, so that the appearance of three separate roof tiles can be achieved. It is also possible to use three separate pieces of glass to cover the six cells, which are laid out on a common backsheet. In this case, gaps 422 and 424 can be sealed with an encapsulant material, establishing a semi-rigid coupling between adjacent tiles. Prefabricating multiple tiles into a rigid or semi-rigid multi-tile module can significantly reduce the complexity in roof installation, because the tiles within the module have been connected with the tabbing strips. Note that the number of tiles included in each multi-tile module can be more or fewer than what is shown in FIG. 4A.

FIG. 4B illustrates a cross-section of an exemplary multi-tile module, according to one embodiment. In this example, multi-tile module 450 can include photovoltaic roof tiles 454, 456, and 458. These tiles can share common backsheet 452, and have three individual glass covers 455, 457, and 459, respectively. Each tile can encapsulate two solar cells. For example, tile 454 can include solar cells 460 and 462 encapsulated between backsheet 452 and glass cover 455. Tabbing strips can be used to provide electrical coupling within each tile and between adjacent tiles. For example, tabbing strip 466 can couple the front electrode of solar cell 460 to the back electrode of solar cell 462, creating a serial connection between these two cells. Similarly, tabbing strip 468 can couple the front electrode of cell 462 to the back electrode of cell 464, creating a serial connection between tile 454 and tile 456.

The gap between two adjacent PV tiles can be filled with encapsulant, protecting tabbing strips interconnecting the two adjacent tiles from the weather elements. For example, encapsulant 470 fills the gap between tiles 454 and 456, protecting tabbing strip 468 from weather elements. Furthermore, the three glass covers, backsheet 452, and the encapsulant together form a semi-rigid construction for multi-tile module 450. This semi-rigid construction can facilitate easier installation while providing a certain degree of flexibility among the tiles.

In addition to the examples shown in FIGS. 4A and 4B, a PV tile may include different forms of photovoltaic structures. For example, in order to reduce internal resistance, each square solar cell shown in FIG. 4A can be divided into multiple (e.g., three) smaller strips, each having edge busbars of different polarities on its two opposite edges. The edge busbars allow the strips to be cascaded one by one to form a serially connected string.

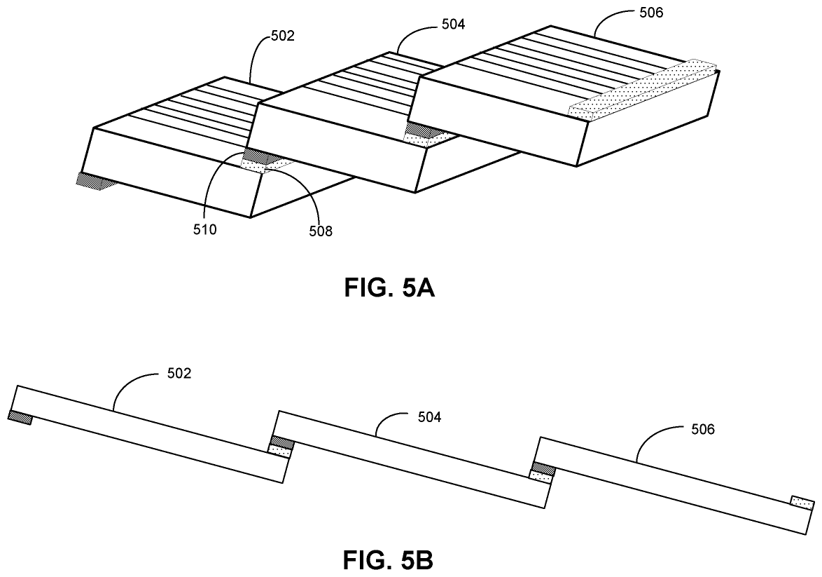

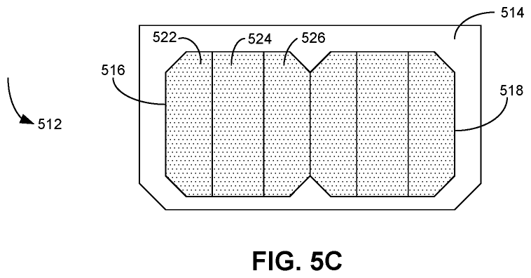

FIG. 5A illustrates a serial connection between three adjacent cascaded photovoltaic strips, according to one embodiment. In FIG. 5A, strips 502, 504, and 506 are stacked in such a way that strip 504 partially underlaps adjacent strip 506 to its right, and overlaps strip 502 to its left. The resulting string of strips forms a cascaded pattern similar to roof shingles. Strips 502 and 504 are electrically coupled in series via edge busbar 508 at the top surface of strip 502 and edge busbar 510 at the bottom surface of strip 504. Strips 502 and 504 can be arranged in such a way that bottom edge busbar 510 is above and in direct contact with top edge busbar 508. The coupling between strips 504 and 506 can be similar.

FIG. 5B illustrates the side view of the string of cascaded strips, according to one embodiment. In the example shown in FIGS. 5A and 5B, the strips can be segments of a six-inch square or pseudo-square solar cell, with each strip having a dimension of approximately two inches by six inches. To reduce shading, the overlapping between adjacent strips should be kept as small as possible. Therefore, in the example shown in FIGS. 5A and 5B, the single busbars (both at the top and the bottom surfaces) can be placed at or near the very edge of the strip. The same cascaded pattern can extend along multiple strips to form a serially connected string, and a number of strings can be coupled in series or parallel. Note that, in FIGS. 5A-5B, the coupling mechanism (e.g., an adhesive layer) that couples the overlapping edge busbars is not shown.

FIG. 5C illustrates an exemplary solar roof tile, according to one embodiment. A solar roof tile 512 includes top glass cover 514 and solar cells 516 and 518. The bottom cover (e.g., backsheet) of solar roof tile 512 is out of view in FIG. 5C. Solar cells 516 and 518 can be conventional square or pseudo-square solar cells, such as six-inch solar cells. In some embodiments, solar cells 516 and 518 can each be divided into three separate pieces of similar size. For example, solar cell 516 can include strips 522, 524, and 526. These strips can be arranged in such a way that adjacent strips are partially overlapped at the edges, similar to the ones shown in FIGS. 5A-5B. For simplicity of illustration, the electrode grids, including the finger lines and edge busbars, of the strips are not shown in FIG. 5C. In addition to the example shown in FIG. 5C, a solar roof tile can contain fewer or more cascaded strips, which can be of various shapes and size.

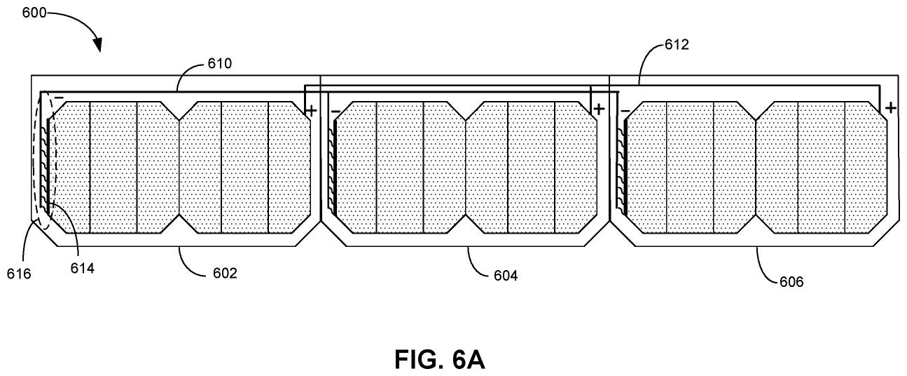

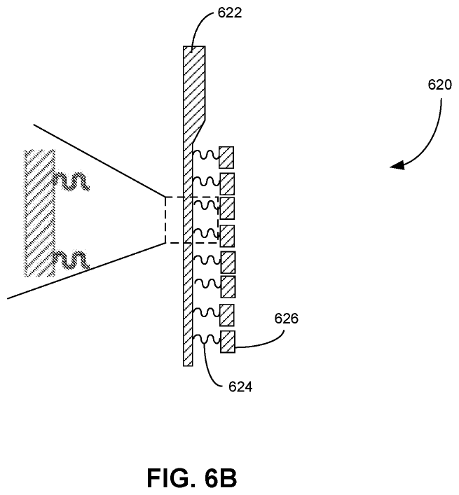

FIG. 6A shows the top view of an exemplary multi-tile module, according to one embodiment. Multi-tile module 600 can include PV roof tiles 602, 604, and 606 arranged side by side. Each PV roof tile can include six cascaded strips encapsulated between the front and back covers, meaning that busbars located at opposite edges of the cascaded string of strips have opposite polarities. For example, if the leftmost edge busbar of the strips in PV roof tile 602 has a positive polarity, then the rightmost edge busbar of the strips will have a negative polarity. Serial connections can be established among the tiles by electrically coupling busbars having opposite polarities, whereas parallel connections can be established among the tiles by electrically coupling busbars having the same polarity.

In the example shown in FIG. 6A, the PV roof tiles are arranged in such a way that their sun-facing sides have the same electrical polarity. As a result, the edge busbars of the same polarity will be on the same left or right edge. For example, the leftmost edge busbar of all PV roof tiles can have a positive polarity and the rightmost edge busbar of all PV roof tiles can have a negative polarity, or vice versa. In FIG. 6A, the left edge busbars of all strips have a negative polarity (indicated by the “−” signs) and are located on the sun-facing (or front) surface of the strips, whereas the right edge busbars of all strips have a positive polarity (indicated by the “+” signs) and are located on the back surface. Depending on the design of the layer structure of the solar cell, the polarity and location of the edge busbars can be different from those shown in FIG. 6A.

A parallel connection among the tiles can be formed by electrically coupling all leftmost busbars together via metal tab 610 and all rightmost busbars together via metal tab 612. Metal tabs 610 and 612 are also known as connection buses and typically can be used for interconnecting individual solar cells or strings. A metal tab can be stamped, cut, or otherwise formed from conductive material, such as copper. Copper is a highly conductive and relatively low-cost connector material. However, other conductive materials such as silver, gold, or aluminum can be used. In particular, silver or gold can be used as a coating material to prevent oxidation of copper or aluminum. In some embodiments, alloys that have been heat-treated to have super-elastic properties can be used for all or part of the metal tab. Suitable alloys may include, for example, copper-zinc-aluminum (CuZnAl), copper-aluminum-nickel (CuAlNi), or copper-aluminum-beryllium (CuAlBe). In addition, the material of the metal tabs disclosed herein can be manipulated in whole or in part to alter mechanical properties. For example, all or part of metal tabs 610 and 612 can be forged (e.g., to increase strength), annealed (e.g., to increase ductility), and/or tempered (e.g. to increase surface hardness).

The coupling between a metal tab and a busbar can be facilitated by a specially designed strain-relief connector. In FIG. 6A, strain-relief connector 616 can be used to couple busbar 614 and metal tab 610. Such strain-relief connectors are needed due to the mismatch of the thermal expansion coefficients between metal (e.g., Cu) and silicon. As shown in FIG. 6A, the metal tabs (e.g., tabs 610 and 612) may cross paths with strain-relief connectors of opposite polarities. To prevent an electrical short of the photovoltaic strips, portions of the metal tabs and/or strain-relief connectors can be coated with an insulation film or wrapped with a sheet of insulation material.

For simplicity of illustration, FIG. 6A does not show the inter-tile spacers that provide support and facilitate mechanical and electrical coupling between adjacent tiles. Detailed descriptions of such inter-tile spacers can be found in U.S. patent application Ser. No. 15/900,636, Attorney Docket Number P0363-1NUS, filed Feb. 20, 2018 and entitled “INTER-TILE SUPPORT FOR SOLAR ROOF TILES,” the disclosure of which is incorporated herein by reference in its entirety.

FIG. 6B shows a detailed view of an exemplary strain-relief connector, according to one embodiment. In FIG. 6B, strain-relief connector 620 can include elongated connection member 622, a number of curved metal wires (e.g., curved metal wire 624), and a number of connection pads (e.g., connection pad 626). The connection pads can be used to couple strain-relief connector 620 to a corresponding edge busbar. Elongated connection member 622 can extend along a direction substantially parallel to the to-be-coupled busbar of a photovoltaic structure. The curved metal wires can extend laterally from elongated connection member 622 in a non-linear manner (i.e., having non-linear geometry), as shown by the amplified view. Non-linear geometry can include paths that centrally follow a curved wire (e.g., a path that extends along a series of centermost points located between outermost edges) or along any face or edge of the wire. A curved wire having non-linear geometry can have, but does not require, symmetry along the path of elongation. For example, one edge, or portion of an edge, of a curved wire can be straight and an opposite edge can include one or more curves, cuts, or extensions. Curved wires having non-linear geometry can include straight portions before, after, and/or between non-linear portions. Non-linear geometry can include propagating paths that extend laterally along a first axis (e.g., X axis) while alternating direction in negative and positive directions of one or more other axes (e.g., Y axis and/or Z axis) that are perpendicular to the first axis, in a repetitive manner, such as a sine wave or helix. While the curved wires disclosed herein use curved profiles, non-linear geometry can be constructed from a series of straight lines; for example, propagating shapes, such as square or sawtooth waves, can form non-linear geometry. These curved wires can relieve the strain generated due to the mismatch of thermal expansion coefficients between the metal connector and the Si-based photovoltaic structure.

In some embodiments, each curved metal wire can be attached to a connection pad. For example, curved metal wire 624 can be attached to connection pad 626. In alternative embodiments, more than one (e.g., two or three) curved wires can be attached to a connection pad. The elongated connection member 622, the curved wires, and the connection pads can be formed (e.g., stamped or cut) from a single piece of material, or they can be attached to each other by any suitable electrical connection, such as by soldering, welding, or bonding. A more detailed description of such strain-relief connectors and the coupling between the strain-relief connectors and the edge busbars can be found in U.S. patent application Ser. No. 15/900,600, Attorney Docket No. P0390-1NUS, filed Feb. 20, 2018, and entitled “METHOD FOR ATTACHING CONNECTOR TO SOLAR CELL ELECTRODES IN A SOLAR ROOF TILE,” the disclosure of which is incorporated herein by reference in its entirety.

Although the strain-relief connectors, which often are made of stamped metal, along with metal tabs or tabbing strips, can provide mechanisms for inter-tile electrical connections, the stamped metal electrodes can often incur a relatively high cost. Moreover, color matching between the stamped electrodes and the top surface of the photovoltaic structures can also be a difficult task. For example, some approaches can involve applying a layer of acrylic paint (e.g., dark blue or black paint) to the top surface of the stamped electrodes. However, such a process can be cumbersome and the acrylic paint layer may not be compatible with the curing process of conductive paste used for bonding the stamped electrodes. In addition, although the strain-relief connectors can mitigate strains caused by the mismatching of the coefficient of thermal expansion (CTE) between Si and metal, they cannot eliminate such strains completely.

Si-Based Bridge Electrode

In some embodiments, a low-cost inter-tile electrical connection mechanism can be provided. More specifically, instead of using strain-relief connectors, a Si-chip-based bridge electrode can be used to facilitate the inter-tile electrical connection. More specifically, the Si chip can include, on its back surface, an edge busbar for electrical coupling to a cascaded string and a number of contact pads for coupling to a metal tab or tabbing strip. The top surface (i.e., the sun-facing surface) of the Si chip can be blank, i.e., it does not include any layered structure nor does it include any metallization.

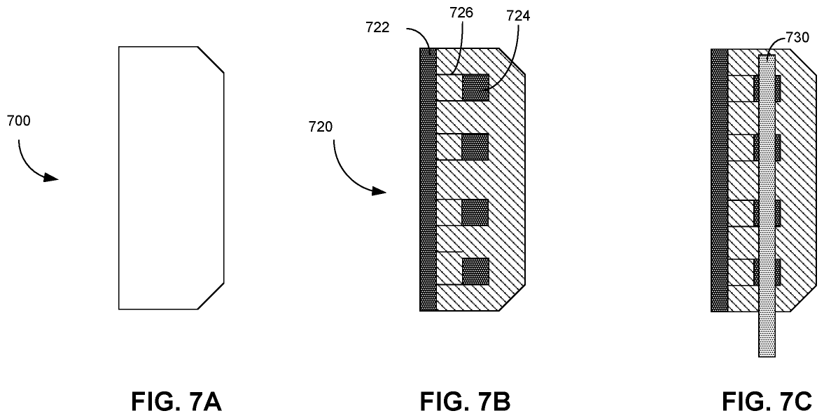

FIG. 7A shows the front surface of an exemplary bridge electrode, according to one embodiment. In some embodiments, the bridge electrode can include a Si substrate, which can be similar to the substrate used for fabricating the photovoltaic structures. In alternative embodiments, the bridge electrode can include other types of substrate, such as glass, plastic, or metal substrate. Moreover, it is also possible to use lower grade Si substrates, such as metallurgical Si (MG-Si) substrate, to fabricate the bridge electrodes. An Si-based (including MG-Si-based) bridge electrode has the advantage of providing color matching and CTE matching.

As shown in FIG. 7A, top surface 700 of a bridge electrode can be blank. In other words, it does not include any solar cell structures or metallization. In some embodiments, the bridge electrode can be similar in size to a photovoltaic strip included in the cascaded string. For example, the size of top surface 700 can be similar to that of the top surface of photovoltaic strip 526 shown in FIG. 5C. Alternatively, to reduce the cost of the bridge electrode and the size of the tile space that is not covered by photovoltaic structures, the bridge electrode can be smaller than a photovoltaic strip. More specifically, the width of the bridge electrode can be narrower than that of the photovoltaic strip. For example, the width of a typical photovoltaic strip can be about two inches (or five centimeters), and the width of the bridge electrode can be about one inch (or 2.5 centimeters). In some embodiments, the width of the bridge electrode can be between one and five centimeters, and the length of the bridge electrode can be substantially the same as the length of the longer edge of the photovoltaic strips.

FIG. 7B shows the back surface of the exemplary bridge electrode, according to one embodiment. In some embodiments, back surface 720 of the bridge electrode can be covered with a thin layer of aluminum (Al). More specifically, the Al layer may cover the entirety of surface 720. In FIG. 7B, back surface 720 of the bridge electrode can also include, on top of the aluminum layer, an edge busbar 722 and multiple contact pads, such as contact pad 724, coupled to edge busbar 722.

Edge busbar 722 can be positioned substantially near an edge of back surface 720 in a way similar to the back-side edge busbar of a photovoltaic strip. In some embodiments, edge busbar 722 can include a layer of silver (Ag), which can have a lower resistivity than Al. Similarly, the contact pads (e.g., contact pad 724) can also include an Ag layer deposited on the Al layer that covers entire back surface 720. The metal traces (e.g., metal trace 726) that connect the contact pads to edge busbar 722 can also include Ag traces. In addition to Ag, copper (Cu) can also be used to form edge busbar 722 and the contact pads due to the low cost and low resistivity of Cu.

The electrical coupling between the bridge electrode and the cascaded string can be similar to the electrical coupling between the two adjacent strips in the cascaded string. More specifically, the bridge electrode can be arranged in such a way that edge busbar 722 overlaps a busbar located on an edge of the cascaded string and an adhesive layer (e.g., an adhesive conductive film or paste) can be used to bond the overlapping busbars. If the bridge electrode is Si-based, this does not significantly change the appearance of the cascaded string. If the bridge electrode is made of a different material, such as glass, one needs to carefully match the color of the top surface of the bridge electrode to that of the cascaded string of photovoltaic strips.

The electrical coupling between the bridge electrode and the metal tab or tabbing strip that connects an electrode in one tile to an electrode in a different tile can be facilitated by a metal strip or tab coupled to the contact pads (e.g., contact pad 724) on the back surface of the bridge electrode. FIG. 7C shows the coupling between a metal strip (e.g., a Cu strip) and the bridge electrode, according to one embodiment. In FIG. 7C, metal strip 730 can be placed in a way such that it runs through the top surface of the multiple contact pads, and an adhesive (e.g., an adhesive conductive film or paste) can be used to bond metal strip 730 to the contact pads, thus achieving electrical and mechanical coupling. Alternatively, the mechanical and electrical coupling between metal strip 730 and the contact pads can be achieved via soldering. In the example shown in FIG. 7C, the width of the contact pads is slightly larger than that of metal strip 730. Larger pads can make the alignment of metal strip 730 relatively easy. However, it is also possible for the contact pads to be narrower than metal strip 730. Compared to the coupling between a strain-relief connector and the edge busbar of a cascaded string, the electrical coupling between metal strip 730 and the edge busbar of the cascaded string provided by the bridge electrode is much more reliable. Moreover, unlike strain-relief connector 616 shown in FIG. 6A, metal strip 730 is placed beneath the bridge electrode, out of view. Therefore, there is no longer a need for color matching, at least for the portion of metal strip 730 covered by the bridge electrode.

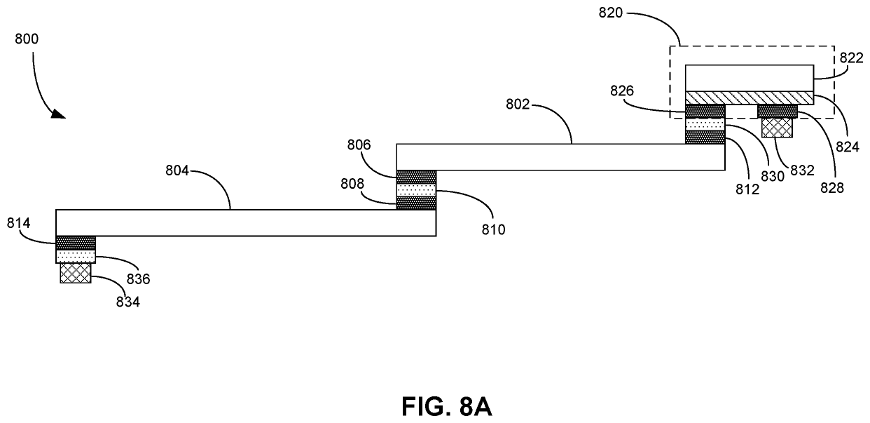

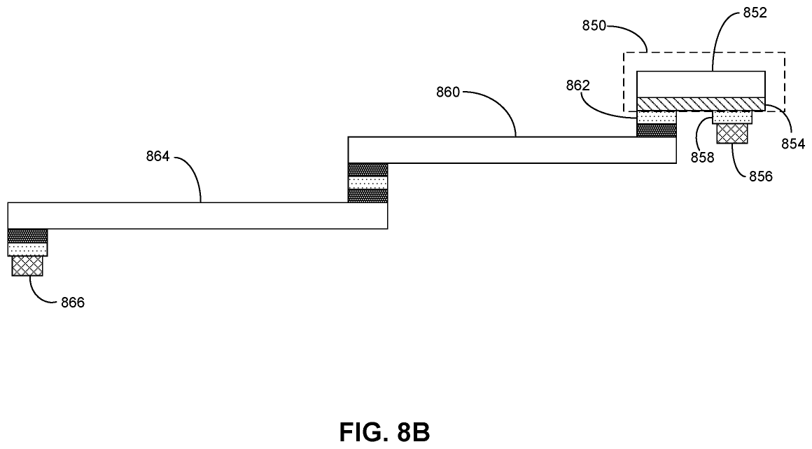

FIG. 8A shows a cross-sectional view of a cascaded photovoltaic string coupled to a bridge electrode, according to an embodiment. Solar roof tile 800 can include front cover 802 and back cover 804. For simplicity of illustration, the different layers are not drawn to scale. Moreover, in FIG. 8A, the cascaded string is shown to include two cascaded strips. In practice, there are usually more (e.g., six) strips included in a cascaded string.

In FIG. 8A, photovoltaic strip 802 and photovoltaic strip 804 can be arranged such that their adjacent edges overlap. More specifically, edge busbar 806 of photovoltaic strip 802 can be stacked on top of edge busbar 808 of photovoltaic strip 804, and adhesive layer 810 can be used to bond edge busbars 806 and 808. In addition to edge busbar 806, photovoltaic strip 802 can include edge busbar 812 on its opposite edge; similarly, in addition to edge busbar 808, photovoltaic strip 804 can include edge busbar 814.

Bridge electrode 820 can include substrate 822, full-back-contact layer 824, edge busbar 826, and contact pad 828. Substrate 822 can be any supporting substrate that has a thickness that is similar to that of photovoltaic strips 802 and 804. In some embodiments, the thickness of substrate 822 can be between 100 and 250 microns. For aesthetic purposes, the color of the top surface of substrate 822 can be similar to that of photovoltaic strips 802 and 804. In one embodiment, substrate 822 can include a dummy Si substrate, i.e., a Si wafer without any additional doping. MG-Si wafers can also be used. In addition to Si, substrate 822 can also be made of other types of material, such as glass or plastic.

Full-back-contact layer 824 can substantially cover the entire back surface of substrate 822. In some embodiments, full-back-contact layer 824 can include an Al layer. Depositing the Al layer can include screen printing or inkjet printing. Edge busbar 826 and contact pad 828 can be formed on full-back-contact layer 824. In some embodiments, edge busbar 826 and contact pad 828 can include a screen printed Ag layer. Alternatively, edge busbar 826 and contact pad 828 can include a Cu layer that is formed using an electroplating technique.

Bridge electrode 820 can be arranged in such a way that edge busbar 826 of bridge electrode 820 is stacked on top of edge busbar 812 of photovoltaic strip 802, and an adhesive layer 830 bonds together edge busbars 826 and 812. In other words, the coupling between bridge electrode 820 and photovoltaic strip 802 can be similar to the coupling between photovoltaic strips 802 and 804. On the other hand, metal strip 832 can couple to contact pad 828 using a soldering technique. Alternatively, an adhesive layer (not shown in FIG. 8A) can also be used to couple metal strip 832 to contact pad 828.

On the opposite end of the cascaded string, connector 834 can couple to bottom edge busbar 814 of photovoltaic strip 804 via adhesive layer 836. In some embodiments, connector 834 can include a metal strip. In an alternative embodiment, connector 834 can include a strain-relief connector. Note that because the strain-relief connector is now on the back side of a photovoltaic strip, there is no longer a need to match the color of the strain-relief connector to the color of the photovoltaic strip.

As one can see from FIG. 8A, metal strip 832 and connector 834 together can provide external electrical connections, thus allowing the cascaded string encapsulated within a solar roof tile to electrically couple to a cascaded string encapsulated within a different solar roof tile.

In the example shown in FIG. 8A, bridge electrode 820 includes full-back-contact layer 824 along with edge busbar 826 and contact pad 828. Current can flow from the cascaded string to metal strip 832 via edge busbar 826, full-back-contact layer 824, and contact pad 828. Because full-back-contact layer 824 covers the entire back surface of bridge electrode 820, it can provide low electrical resistance. In some embodiments, edge busbar 826 and contact pad 828 can be optional, and it is possible for the current to flow from the cascaded string to a metal strip via the full-back-contact layer only.

FIG. 8B shows a cross-sectional view of a cascaded photovoltaic string coupled to a bridge electrode, according to an embodiment. In FIG. 8B, bridge electrode 850 can include substrate 852 and full-back-contact layer 854, which can be similar to substrate 822 and full-back-contact layer 824 shown in FIG. 8A. More specifically, full-back-contact layer 854 can be coupled to the front-side edge busbar of photovoltaic strip 860 via adhesive layer 862. Similarly, metal strip 856 can couple to full-back-contact layer 854 via adhesive layer 858. The coupling between photovoltaic strips 860 and 864 can be similar to the coupling between photovoltaic strips 802 and 804. Connector 866 can couple to the back-side edge busbar of photovoltaic strip 864.

In some embodiments, the full-back-contact layer can be optional, and an edge busbar and multiple contact pads can be formed directly on the back surface of the substrate of the bridge electrode. In addition, metal traces (e.g., Ag or Cu traces) can be formed between the edge busbar and contact pads.

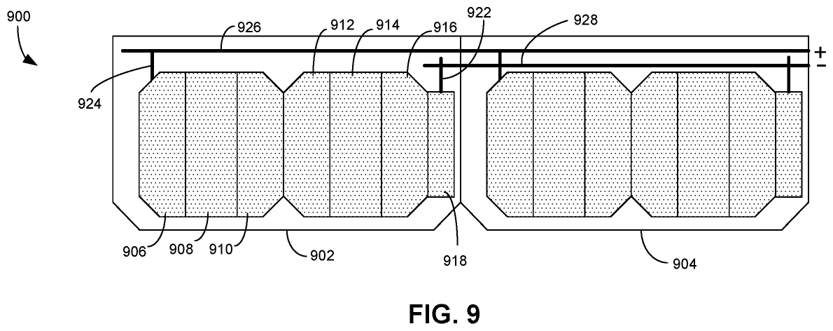

FIG. 9 shows the top view of an exemplary multi-tile module, according to one embodiment. Multi-tile module 900 can include tiles 902 and 904. Each tile can include a cascaded string that includes multiple cascaded strips. For example, tile 902 can include cascaded strips 906, 908, 910, 912, 914, and 916. More specifically, the strips can be arranged in a way similar to the one shown in FIGS. 5A-5B, forming a serial connection.

In addition to the photovoltaic strips, each tile can also include a bridge electrode positioned adjacent to an edge photovoltaic strip. For example, tile 902 can include bridge electrode 918 positioned adjacent to photovoltaic strip 916, which is at the edge of the cascaded string. More specifically, bridge electrode 918 can be arranged in such a way that an edge of bridge electrode 918 overlaps an edge of photovoltaic strip 916. The surface of bridge electrode 918 can have a similar appearance as that of the surface of cascaded strips 906-916, thus ensuring a uniform appearance of tile 902. Note that, for aesthetic effect, the color of bottom cover of tile 902 can also be similar to that of cascaded strips 906-916 and bridge electrode 918.

In FIG. 9, each cascaded string can be coupled to two external electrodes, one for each polarity. More specifically, tile 902 can include electrode 922 coupled to a back-side edge busbar of strip 906 and electrode 924 coupled to a front-side edge busbar of strip 916 via bridge electrode 918. In the example shown in FIG. 9, electrode 922 is the negative polarity electrode and electrode 924 is the positive polarity electrode. Other arrangements of polarities can also be possible. To enable inter-tile electrical connections, extension metal strips (e.g., extension metal strips 926 and 928) can be used to couple external electrodes of one tile to external electrodes of an adjacent tile, thus achieving inter-tile electrical coupling.

Parallel or in-series electrical coupling between the solar roof tiles can be achieved by configuring the extension metal strips. In the example shown in FIG. 9, extension metal strip 926 couples the positive polarity electrodes of tiles 902 and 904, whereas metal strip 928 couples the negative polarity electrodes of tiles 902 and 904. As a result, parallel coupling between tiles 902 and 904 can be achieved. Different types of electrical coupling can also be achieved by configuring extension metal strips differently. In the example shown in FIG. 9, tile module 900 includes two tiles. In practice, depending on the design, a tile module can include a different number (e.g., three) of tiles.

### Fabrication of a Photovoltaic Roof Tile

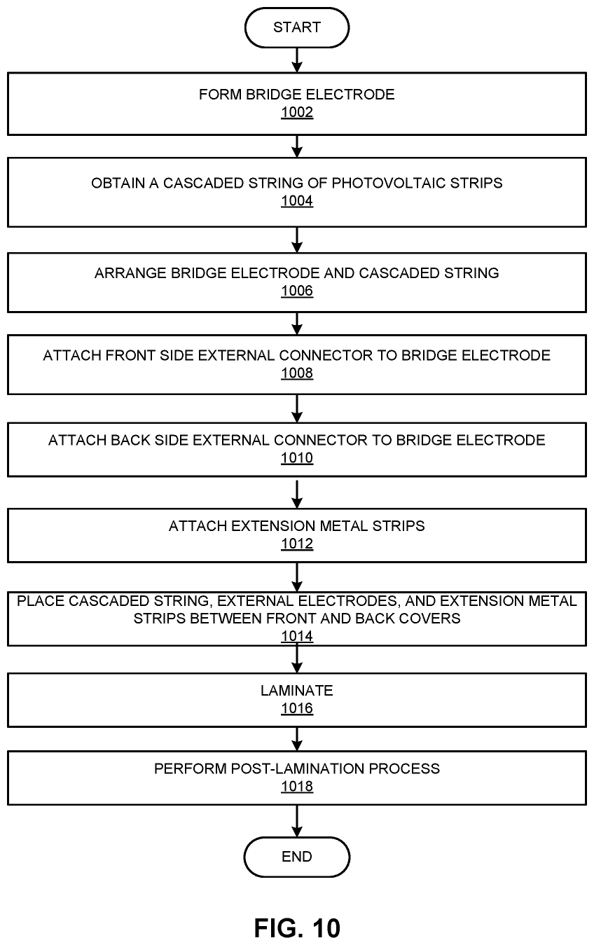

FIG. 10 presents a flowchart illustrating an exemplary process for fabricating a photovoltaic tile module, according to an embodiment. The photovoltaic tile module can be a single-tile module or a multi-tile module. During fabrication, a bridge electrode can also be formed (operation 1002) and a cascaded string of photovoltaic strips can be obtained (operation 1004).

The bridge electrode can be formed by depositing one or more metallization layers on the back surface (i.e., the surface facing away from the sun) of a dummy or blank substrate, such as a Si or glass substrate. In some embodiments, the metallization layers can include a full-back-contact layer and an optional contact layer, which can include an edge busbar and a number of contact pads. The full-back-contact layer can include a screen-printed Al layer and the optional contact layer can include a screen-printed Ag layer.

The photovoltaic strips can be obtained by dividing a standard square or pseudo-square solar cell into multiple pieces, and a string of strips can be formed by cascading multiple strips at the edges. The cascading forms a serial connection among the strips. In some embodiments, each individual solar roof tile may include one string, and each string can include six cascaded strips. Detailed descriptions about the formation of a cascaded string of photovoltaic strips can be found in U.S. patent application Ser. No. 14/826,129, Attorney Docket No. P103-3NUS, entitled “PHOTOVOLTAIC STRUCTURE CLEAVING SYSTEM,” filed Aug. 13, 2015; U.S. patent application Ser. No. 14/866,776, Attorney Docket No. P103-4NUS, entitled “SYSTEMS AND METHODS FOR CASCADING PHOTOVOLTAIC STRUCTURES,” filed Sep. 25, 2015; U.S. patent application Ser. No. 14/804,306, Attorney Docket No. P103-5NUS, entitled “SYSTEMS AND METHODS FOR SCRIBING PHOTOVOLTAIC STRUCTURES,” filed Jul. 20, 2015; U.S. patent application Ser. No. 14/866,806, Attorney Docket No. P103-6NUS, entitled “METHODS AND SYSTEMS FOR PRECISION APPLICATION OF CONDUCTIVE ADHESIVE PASTE ON PHOTOVOLTAIC STRUCTURES,” filed Sep. 25, 2015; and U.S. patent application Ser. No. 14/866,817, Attorney Docket No. P103-7NUS, entitled “SYSTEMS AND METHODS FOR TARGETED ANNEALING OF PHOTOVOLTAIC STRUCTURES,” filed Sep. 25, 2015; the disclosures of which are incorporated herein by reference in their entirety.

In some embodiments, instead of conductive paste, electrical and mechanical bonding between the adjacent strips at their corresponding edges can be achieved via adhesive conductive films. Detailed descriptions about the bonding of adjacent photovoltaic strips using adhesive conductive films can be found in U.S. patent application Ser. No. ______, Attorney Docket No. P0399-1NUS, entitled “CASCADED SOLAR CELL STRING USING ADHESIVE CONDUCTIVE FILM,” filed ______, 2018, the disclosure of which is incorporated herein by reference in its entirety.

Subsequently, the bridge electrode can be arranged adjacent to the edge of the cascaded string (operation 1006). More specifically, an edge of the back surface of the bridge electrode can stack on top of an edge busbar on the front surface (i.e., the sun-facing surface) of the cascaded string. If the bridge electrode includes an edge busbar on its back surface, such an edge busbar can overlap the front-side edge busbar of the cascaded string in a way similar to the cascading of two adjacent strips. The coupling between the bridge electrode and the strip at the end of the string can be similar to the coupling between two adjacent strips. A front side external connector of the cascaded string can be attached to the front side electrode (operation 1008). More specifically, the front side external connector can couple to the metal layers on the back surface of the bridge electrode. If the bridge electrode includes Ag-based contact or soldering pads, the front side external connector can be attached to the contact or soldering pads via conductive paste or solder.

On the other end of the cascaded string, a back side external connector can also couple to the edge busbar on the back surface (operation 1010). In some embodiments, the external connector can include a strain-relief connector. Various electrical coupling methods can be used to attach the strain-relief connectors to the busbars, including but not limited to: soldering, welding, or bonding with electrically conductive adhesive (ECA). Alternatively, a metal strip can be used as the back side external connector. In addition, extension metal strips can also be attached to the external connectors to function as lead electrodes (operation 1012).

Subsequently, the cascaded string of PV structures along with the attached external connectors and extension metal strips can then be placed between a front cover and a back cover, embedded in encapsulant (operation 1014). A lamination operation can be performed to encapsulate the string of PV structures along with the attached external connectors inside the front and back covers (operation 1016). A post-lamination process (e.g., trimming of overflowed encapsulant and attachment of other roofing components) can then be performed to complete the fabrication of a PV roof tile (operation 1018).

In some embodiments, instead of a single roof tile, multiple tiles can be fabricated together to form a multi-tile module. In such a scenario, the extension metal strips can go across a tile spacer located between adjacent tiles, thus achieving inter-tile electrical coupling within the multi-tile module.

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

1. A photovoltaic roof tile, comprising:
a plurality of photovoltaic structures positioned between a front cover and a back cover;
a bridge electrode coupled to a front-side busbar belonging to a photovoltaic structure; and
a metallic strip positioned on a back side of the bridge electrode;
wherein the bridge electrode comprises a substrate and at least one metallization layer positioned on a back surface of the substrate, and wherein the metallization layer is electrically coupled to both the front-side busbar and the metallic strip, thereby enabling electrical coupling between the front-side busbar and the metallic strip.

2. The photovoltaic roof tile of claim 1, wherein a respective photovoltaic structure comprises a front-side edge busbar positioned near an edge of a front surface and a back-side edge busbar positioned near an opposite edge of a back surface, and wherein the plurality of photovoltaic structures is arranged in such a way that the back-side edge busbar of a first photovoltaic structure overlaps the front-side edge busbar of an adjacent photovoltaic structure, thereby resulting in the plurality of photovoltaic structures forming a serially coupled string.

3. The photovoltaic roof tile of claim 2, wherein the metallization layer is coupled to a front-side edge busbar positioned at an end of the serially coupled string.

4. The photovoltaic roof tile of claim 1, wherein the substrate of the bridge electrode comprises one of:
a Si substrate;
a glass substrate; and
a plastic substrate.

5. The photovoltaic roof tile of claim 1, wherein the bridge electrode comprises one or more of:
an Al layer configured to substantially cover the back surface of the substrate; and
a contact layer comprising Ag.

6. The photovoltaic roof tile of claim 5, wherein the contact layer comprises an edge busbar and a plurality of contact pads.

7. The photovoltaic roof tile of claim 6, wherein the bridge electrode is arranged in such a way that the edge busbar of the contact layer overlaps the front-side busbar of the photovoltaic structures.

8. The photovoltaic roof tile of claim 6, wherein the metallic strip is coupled to the contact pads.

9. The photovoltaic roof tile of claim 5, wherein the Al layer and the contact layer are formed using a screen printing technique.

10. The photovoltaic roof tile of claim 1, further comprising an external connector coupled to a back-side busbar belonging to a photovoltaic structure.

11-20. (canceled)
